(19) United States
(12) Patent Application Publication
(10) Pub. No.: US 2017/0192453 A1
(43) Pub. Date: Jul. 6, 2017

(54) WEARABLE DEVICE WITH A CHIP ON FILM PACKAGE STRUCTURE

(71) Applicant: Novatek Microelectronics Corp., Hsinchu (TW)

(72) Inventors: Wen-Ching Huang, Hsinchu City (TW); Shu-Huan Hsieh, Changhua County (TW); Tai-Hung Lin, Hsinchu City (TW); Feng-Ting Pai, Hsinchu City (TW)

(73) Assignee: Novatek Microelectronics Corp., Hsinchu (TW)

(21) Appl. No.: 15/257,937

(22) Filed: Sep. 7, 2016

Related U.S. Application Data
(60) Provisional application No. 62/273,408, filed on Dec. 30, 2015.

(51) Int. Cl. G06F 1/16; H05K 1/18; H05K 1/11; H05K 1/02

(52) U.S. Cl. CPC G06F 1/163; G06F 1/1637; H05K 1/028; H05K 1/18; H05K 1/11; G09G 5/003

(57) ABSTRACT

A wearable device with a chip on film package structure is provided. The wearable device with the chip on film package structure includes a display device and a chip device. The display device includes a display area and a non-display area. The non-display area includes a bonding area. The chip device is bonded to the display device via the chip on film package structure. The chip device is configured to drive the display device to display images. The chip on film package structure includes a film having a first end and a second end. The chip device is located on the film, and the first end of the film is bonded to the bonding area of the display device.

### CROSS-REFERENCE TO RELATED APPLICATION

This application claims the priority benefits of U.S. provisional application Ser. No. 62/273,408, filed on Dec. 30, 2015. The entirety of the above-mentioned patent application is hereby incorporated by reference herein and made a part of this specification.

### BACKGROUND OF THE INVENTION

1. Field of the Invention

The invention generally relates to a device, in particular, to a wearable device with a chip on film (COF) package structure.

2. Description of Related Art

Development of wearable devices or computers is accelerating with advances in technologies. Here, wearable devices refer to electronic devices that a user may naturally wear, like clothes, watches, glasses, and accessories. Wearable devices may achieve better portability than smart-phones or tablet computers. Wearable devices usually include flat panel displays for displaying information to satisfy user requirements. In related arts, the flat panel displays have bonding areas for packaging with driver chips in a chip on glass (COG) package structure. However, the bonding areas of the flat panel displays can not be reduced due to the COG package structure.

Hence, how to manufacture a wearable device that a display device thereof has a smaller bonding area and satisfactory frameless property is one of the most important topics in the pertinent field.

### SUMMARY OF THE INVENTION

Accordingly, the invention is directed to a wearable device with a chip on film package structure capable of providing a frameless property for a display device thereof.

The invention provides a wearable device with a chip on film package structure. The wearable device with the chip on film package structure includes a display device and a chip device. The display device includes a display area and a non-display area. The non-display area includes a bonding area. The chip device is bonded to the display device via the chip on film package structure. The chip device is configured to drive the display device to display images. The chip on film package structure includes a film having a first end and a second end. The chip device is located on the film, and the first end of the film is bonded to the bonding area of the display device.

In an embodiment of the invention, the film further includes at least one electrical device and a connector device. An electrical signal is transmitted from the at least one electrical device or the connector device to the chip device via the film.

In an embodiment of the invention, a distance between the chip device and the at least one electrical device is larger than 1.5 millimetres.

In an embodiment of the invention, the wearable device with the chip on film package structure further includes a printed circuit board. The printed circuit board includes at least one electrical device, a connector device, and a flexible printed circuit. The second end of the film is bonded to the printed circuit board via the flexible printed circuit. An electrical signal is transmitted from the at least one electrical device or the connector device to the chip device via the flexible printed circuit and the film.

In an embodiment of the invention, an inner lead bonding pitch of the film is between 8 micrometres to 40 micrometres.

In an embodiment of the invention, an outer lead bonding pitch of the film is between 15 micrometres to 500 micrometres.

In an embodiment of the invention, a shape of the film is determined according to a mechanism of the display device.

In an embodiment of the invention, the shape of the film is a rectangle.

In an embodiment of the invention, a ratio of a size of the bonding area and a size of the display device is smaller than 3%.

According to the above descriptions, in the embodiments of the invention, the chip device is bonded to the display device via the chip on film package structure. Accordingly, the bonding area of the non-display area is reduced to provide the frameless property for the display device.

In order to make the aforementioned and other features and advantages of the invention more comprehensible, several embodiments accompanied with figures are described in detail below.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIG. 1 illustrates a schematic diagram of a wearable device with a chip on film package structure according to an embodiment of the invention.

FIG. 2 illustrates a schematic diagram of a display device depicted in FIG. 1 according to an embodiment of the invention.

FIG. 3 illustrates a schematic diagram of a chip on film package structure depicted in FIG. 1 according to an embodiment of the invention.

FIG. 4 illustrates a schematic diagram of a wearable device with a chip on film package structure according to another embodiment of the invention.

FIG. 5 illustrates a schematic diagram of a wearable device with a chip on glass package structure according to a related art of the invention.

### DESCRIPTION OF THE EMBODIMENTS

Reference will now be made in detail to the present preferred embodiments of the invention, examples of which are illustrated in the accompanying drawings. Wherever possible, the same reference numbers are used in the drawings and the description to refer to the same or like parts.

Embodiments are provided below to describe the present disclosure in detail, though the present disclosure is not limited to the provided embodiments, and the provided embodiments can be suitably combined. The term “coupling/coupled” used in this specification (including claims) of the present application may refer to any direct or indirect connection means. For example, “a first device is coupled to a second device” should be interpreted as “the first device is directly connected to the second device” or “the first device is indirectly connected to the second device through other devices or connection means.” In addition, the term “signal” can refer to a current, a voltage, a charge, a temperature, data, electromagnetic wave or any one or multiple signals.

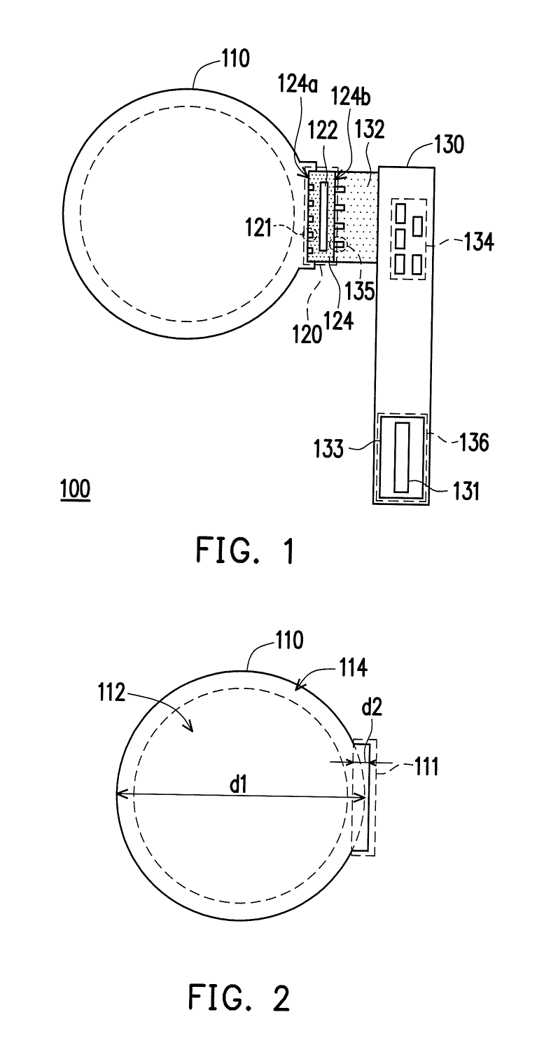

FIG. 1 illustrates a schematic diagram of a wearable device with a chip on film package structure according to an embodiment of the invention. FIG. 2 illustrates a schematic diagram of a display device depicted in FIG. 1 according to an embodiment of the invention. Referring to FIG. 1 and FIG. 2, a wearable device 100 of the present embodiment includes a display device 110, a chip device 122 and a printed circuit board 130. In the present embodiment, the chip device 122 drives the display device 110 to display images according to an electrical signal from the printed circuit board 130. The chip device 122 is bonded to the display device 110 via the chip on film package structure 120. The chip on film package structure 120 includes a film 124, and the chip device 122 is located on the film 124. In the present embodiment, the chip on film package structure 120 may be implemented by using any type of chip on film package in this field. The invention is not intended to limit the type of package structure. Therefore, the chip on film package structure 120 and implementation thereof can be understood sufficiently from the teaching, suggestion, and illustration of the common knowledge of this field. Thus, details thereof are not repeated hereinafter.

To be specific, the display device 110 includes a display area 112 and a non-display area 114, and the non-display area 114 includes a bonding area 111 for electrical bonding in the present embodiment. The film 124 has a first end 124a and a second end 124b. The first end 124a of the film 124 is bonded to the bonding area 111 of the display device 110 via a plurality of electrical pads 121. The second end 124b of the film 124 is bonded to the printed circuit board 130 via a flexible printed circuit 132. In the present embodiment, the second end 124b of the film 124 connects to the flexible printed circuit 132 for signal input, and the first end 124a of the film 124 connects to the non-display area 114 for signal output. The flexible printed circuit 132 includes a plurality of electrical pads 135. The flexible printed circuit 132 connects to the film 124 via the pads 135. In one embodiment, a thin layer of tin metal or gold metal may be plated on the outer surfaces of the electrical pads 121 or 135 to increase lamination accuracy and bonding force. In the present embodiment, by using the chip on film package structure 120, the size of the bonding area 111 is reduced.

In one embodiment, the display device 110 may include flat panel displays, curved panel displays or 3D displays, including Liquid Crystal Display (LCD), Plasma Display Panel (PDP), Organic Light Emitting Display (OLED), Field Emission Display (FED), Electro-Phoretic Display (EPD) or Light Emitting Diode Display and the like, which are not limited in the invention.

In the present embodiment, the printed circuit board 130 includes the flexible printed circuit 132, at least one electrical device 134, and a connector device 136. The at least one electrical device 134 may include one or more active components, passive components or other suitable components, and the invention is not limited thereto. The connector device 136 includes a connector 131 and a stiffener 133. The connector 131 is disposed on a first surface of the printed circuit board 130 that the at least one electrical device 134 locates. The stiffener 133 is disposed on a corresponding location on a second surface of the printed circuit board 130. The first surface is opposite to the second surface. In the present embodiment, the printed circuit board 130 connects to an external circuit (not shown) by using the connector 131, and the stiffener 133 is configured to support the connector 131 on the printed circuit board 130. The external circuit may input the electrical signal to the printed circuit board 130 via the connector 131. Accordingly, the electrical signal is transmitted from the at least one electrical device 134 or the connector device 136 to the chip device 122 via the flexible printed circuit 132 and the film 124.

Referring to FIG. 2, a ratio of a size of the bonding area 111 and a size of the display device 110 is smaller than 3% in the present embodiment. For instance, a shape of the display device 110 is a circle, and the size of the display device 110 is measured in terms of a diameter d1, e.g. about 1.5 inch, of the circle, as depicted in FIG. 2. A shape of the bonding area 111 is a rectangle, and the size of the display device 110 is measured in terms of a width d2, e.g. about 1 millimetre, of the rectangle, as depicted in FIG. 2. Accordingly, the ratio of the size of the bonding area 111 and the size of the display device 110 is smaller than 3% in the present embodiment. In the present embodiment, the foregoing sizes and shapes of the bonding area 111 and the display device 110 are exemplarily disclosed for example, and not intended to limit the invention but may be adjusted according to the actual design requirements.

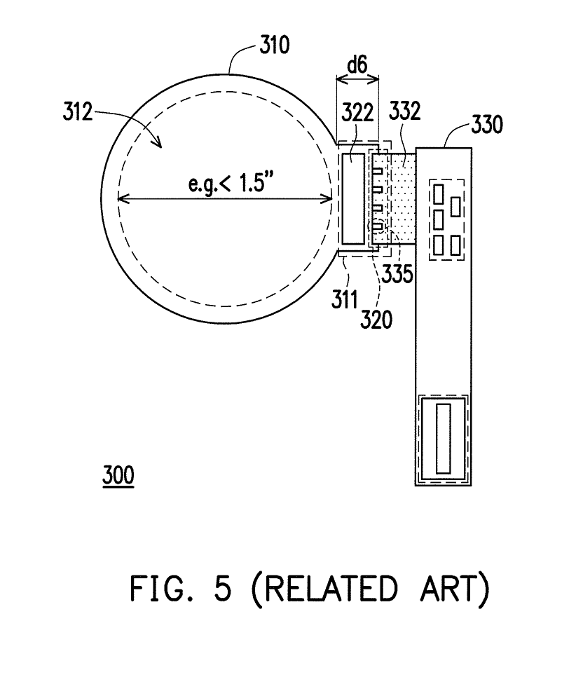

FIG. 5 illustrates a schematic diagram of a wearable device with a chip on glass package structure according to a related art of the invention. Referring to FIG. 1, FIG. 2 and FIG. 5, a wearable device 300 of the related art includes a display device 310, a chip device 322 and a printed circuit board 330. In the related art, the chip device 322 is bonded to the display device 310 via a chip on glass (COG) package structure 320. Since the display device 310 is small, such as a display area 312 thereof smaller than 1.5 inches as illustrated in FIG. 5, a large bonding area 311 having a width d6 is necessary for package. The width d6 of the bonding area 311 is larger than the width d2 of the bonding area 111. The flexible printed circuit 332 connects to the bonding area 311 via the pads 335. To reduce the width d6 of the bonding area 311, the wearable device 100 with the chip on film package structure 120 of the present embodiment is provided. Compared to the wearable device with the chip on glass package structure, the chip on film package structure 120 is adopted for the display device 110, and the width d2 of the bonding area 111 may be reduced from 3 millimetres to 1 millimetre, so that the frameless property of the display device 110 is provided. The frameless property means that the display device 110 has the smaller non-display area 114 or the smaller bonding area 111. Due to the frameless property, the panel utilization is improved, and the thickness of the bonding area 111 is reduced.

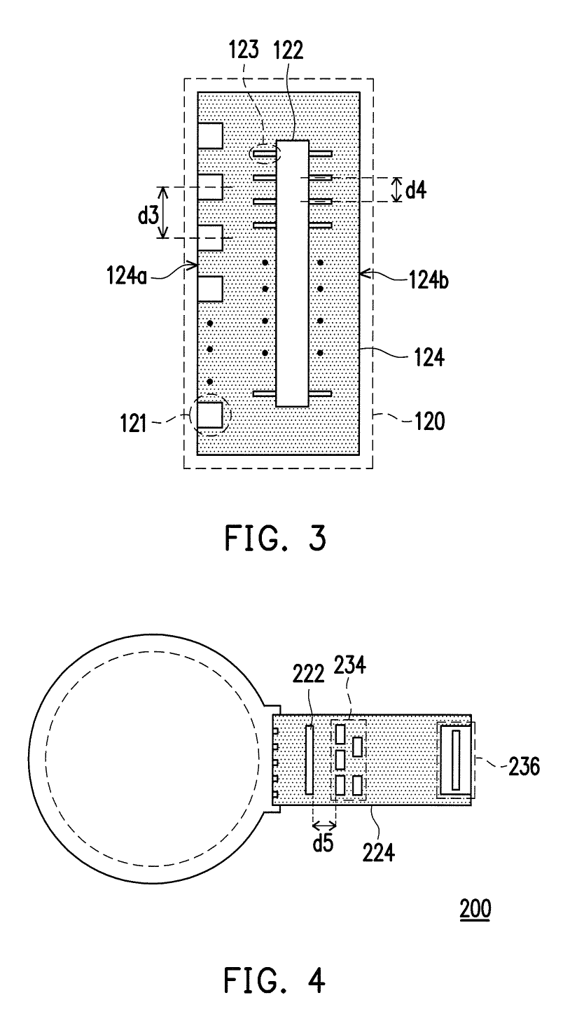

FIG. 3 illustrates a schematic diagram of a chip on film package structure depicted in FIG. 1 according to an embodiment of the invention. Referring to FIG. 3, the chip device 122 is mounted on the film 124 in manner of intermetallic compound (IMC) by using inner leading bounding pads 123 in the present embodiment. The pads 121 serve as outer leading bounding pads. Electrical paths, e.g. metal wires, are correspondingly fanned out from the inner leading bounding pads 123 to the outer leading bounding pads 121 for signal transmission. In one embodiment, a thin layer of tin metal or gold metal may be plated on the outer surfaces of the inner leading bounding pads 123 and the outer leading bounding pads 121 to increase lamination accuracy and bonding force. In the present embodiment, the outer lead bonding pitch d3 of the film 124 is between 15 micrometres to 500 micrometres, and the inner lead bonding pitch d4 of the film 124 is between 8 micrometres to 40 micrometres. The foregoing sizes of the bonding pitches d3 and d4 are exemplarily disclosed for example, and not intended to limit the invention but may be adjusted according to the actual design requirements.

In the present embodiment, the shape of the film 124 is a rectangle for example, but the invention is not limited thereto. In one embodiment, the shape of the film 124 is determined according to a mechanism of the display device 110. The mechanism is the display device 110 designed to transform input forces and movement into a desired set of output forces and the movement. The mechanism may include moving components, friction devices, and structural components, as well as a variety of specialized machine elements. The film 124 may locate in a mechanism space between these components, components and devices, and the shape of the film 124 is determined according to the mechanism of the display device 110. The mechanism of the display device 110 and implementation thereof can be understood sufficiently from the teaching, suggestion, and illustration of the common knowledge of this field. Thus, details thereof are not repeated hereinafter.

In one embodiment, an object may be adhered to a surface of the film 124 to solve the problems of heat radiation and electromagnetic interference. The object may be selected from one of a metallic sheet and a sheet including carbon components. Due to the reduced size of the mechanism, the film 124 may include one or more than one metal layers to increase the number of output channels. The structure of the film 124 is adjustable according to the actual design requirements.

FIG. 4 illustrates a schematic diagram of a wearable device with a chip on film package structure according to another embodiment of the invention. Referring to FIG. 1 and FIG. 4, the wearable device 200 of the present embodiment is similar to the wearable device 100 depicted in FIG. 1, and the main difference therebetween, for example, lies in that the film 224 further includes at least one electrical device 234 and a connector device 236. The at least one electrical device 234 and the connector device 236 are mounted on the film 224 in surface mount technology (SMT), and an electrical signal is transmitted from the at least one electrical device 234 or the connector device 236 to the chip device 222 via the film 224.

In the present embodiment, a distance d5 between the chip device 222 and the at least one electrical device 234 is larger than 1.5 millimetres for device protection. For example, the distance d5 larger than 1.5 millimetres may protect the chip device 222 from being damaged while the surface mount technology are executed. In the present embodiment, the size of the foregoing distance d5 is exemplarily disclosed for example, and not intended to limit the invention but may be adjusted according to the actual design requirements.

In one embodiment, the devices mounted on the film 224 may be bonded onto the film 224 in surface mount technology while the film 224 is manufactured. In another embodiment, the foregoing devices may be also bonded onto the film 224 after the inner lead bounding pads are formed.

Besides, the wearable device 200 described in the present embodiment of the invention is sufficiently taught, suggested, and embodied in the embodiments illustrated in FIG. 1 to FIG. 3, and therefore no further description is provided herein.

In summary, in the exemplary embodiment of the invention, the chip on film package structure is adopted for the connection between the display device and the chip device instead of the chip on glass package structure. The size of the bonding area of the display device is reduced, so that the frameless property of the display device is provided.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

What is claimed is:

1. A wearable device with a chip on film package structure, comprising:
a display device comprising a display area and a non-display area, wherein the non-display area comprises a bonding area; and
a chip device bonded to the display device via the chip on film package structure, and configured to drive the display device to display images, wherein the chip on film package structure comprises a film having a first end and a second end, the chip device is located on the film, and the first end of the film is bonded to the bonding area of the display device.

2. The wearable device with the chip on film package structure according to claim 1, wherein the film further comprises at least one electrical device and a connector device, and an electrical signal is transmitted from the at least one electrical device or the connector device to the chip device via the film.

3. The wearable device with the chip on film package structure according to claim 2, wherein a distance between the chip device and the at least one electrical device is larger than 1.5 millimetres.

4. The wearable device with the chip on film package structure according to claim 1, further comprising:
a printed circuit board comprising at least one electrical device, a connector device, and a flexible printed circuit, wherein the second end of the film is bonded to the printed circuit board via the flexible printed circuit, and an electrical signal is transmitted from the at least one electrical device or the connector device to the chip device via the flexible printed circuit and the film.

5. The wearable device with the chip on film package structure according to claim 1, wherein an inner lead bonding pitch of the film is between 8 micrometres to 40 micrometres.

6. The wearable device with the chip on film package structure according to claim 1, wherein an outer lead bonding pitch of the film is between 15 micrometres to 500 micrometres.

7. The wearable device with the chip on film package structure according to claim 1, wherein a shape of the film is determined according to a mechanism of the display device.

8. The wearable device with the chip on film package structure according to claim 7, wherein the shape of the film is a rectangle.

9. The wearable device with the chip on film package structure according to claim 1, wherein a ratio of a size of the bonding area and a size of the display device is smaller than 3%.
